(19) United States
(12) Patent Application Publication
(10) Pub. No.: US 2024/0255845 A1
(43) Pub. Date: Aug. 1, 2024

(54) PHOTORESIST COMPOSITION

(71) Applicant: SAMSUNG ELECTRONICS CO., LTD., SUWON-SI (KR)

(72) Inventors: Seungyeol Baek, Suwon-si (KR); Chawon Koh, Suwon-si (KR); Jiyoung Park, Suwon-si (KR); Tsunehiro Nishi, Suwon-si (KR); Wonjoon Son, Suwon-si (KR)

(21) Appl. No.: 18/543,114

(22) Filed: Dec. 18, 2023

(30) Foreign Application Priority Data
Jan. 10, 2023 (KR) 10-2023-0003514

(51) Int. Cl. G03F 7/004; C07F 7/22

(52) U.S. Cl. CPC G03F 7/0042; C07F 7/2284

(57) ABSTRACT

A photoresist composition includes an organometallic compound represented by Formula 1.

### CROSS-REFERENCE TO RELATED APPLICATION

This application is based on and claims priority under 35 U.S.C. § 119 to Korean Patent Application No. 10-2023-0003514, filed on Jan. 10, 2023, in the Korean Intellectual Property Office, the disclosure of which is incorporated by reference herein in its entirety.

### BACKGROUND

The inventive concept relates to a photoresist composition, and more particularly, to a photoresist composition including an organometallic compound.

Due to the advance of electronics technology, semiconductor devices have been rapidly down-scaled recently. Therefore, photolithography processes having an advantage in implementing fine patterns are of interest. It is necessary to develop a photoresist composition capable of improving sensitivity, critical dimension (CD) uniformity, and line edge roughness (LER), while ensuring excellent etch resistance and resolution, and in particular, it is necessary to develop a photoresist composition including a highly reactive component and thus exhibiting improved sensitivity to light and improved storage stability.

### SUMMARY

The inventive concept provides a photoresist composition exhibiting improved storage stability, as well as exhibiting excellent pattern formation properties, such as sensitivity, critical dimension (CD) uniformity, and line edge roughness (LER), in a photolithography process for fabricating an integrated circuit device.

According to an aspect of the inventive concept, there is provided a photoresist composition including an organometallic compound represented by Formula 1.

M(L¹)(L²)ₐ(R¹)_{b}(R²)_{c} [Formula 1]

(in Formula 1, M is a metal, L¹ is a tridentate ligand or a tetradentate ligand, L² is a monodenatate ligand or a bidentate ligand, R¹ and R² are each independently a substituted or unsubstituted C1 to C30 hydrocarbon group, a, b, and c are each an integer of 0, 1, or 2, a+b+c≤5, and 1≤b+c).

According to another aspect of the inventive concept, there is provided a photoresist composition including an organometallic compound represented by Formula 1.

M(L¹)(L²)ₐ(R¹)_{b}(R²)_{c} [Formula 1]

(in Formula 1, M, which is a central metal, is Sn or Sb, L¹ is a tridentate ligand or a tetradentate ligand, L² is a monodenatate ligand or a bidentate ligand, R¹ and R² are each independently a substituted or unsubstituted C1 to C30 hydrocarbon group, a, b, and c are each an integer of 0, 1, or 2, a+b+c≤5, and 1≤b+c).

According to yet another aspect of the inventive concept, there is provided a photoresist composition including an organometallic compound represented by Formula 1 and a solvent.

M(L¹)(L²)ₐ(R¹)_{b}(R²)_{c} [Formula 1]

(in Formula 1, M, which is a central metal, is Sn or Sb, L¹ is one of ligands represented by Formula 2, Formula 5, and Formula 8, L² is a monodenatate ligand or a bidentate ligand, R¹ and R² are each independently a substituted or unsubstituted C1 to C30 hydrocarbon group, a, b, and c are each an integer of 0, 1, or 2, a+b+c≤5, and 1≤b+c),

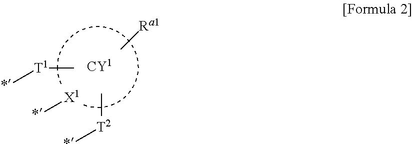

(in Formula 2, CY¹, which is a ring, is a C2 to C30 heterocyclic group, R^{a1} is hydrogen or a substituted or unsubstituted C1 to C30 hydrocarbon group, X¹ is S, O, N, or N(R^{a2}), R^{a2} is hydrogen or a substituted or unsubstituted C1 to C20 hydrocarbon group, T¹ and T² are each independently *-T^{a1}-N(R^{a3})—*′, *-T^{a2}-O—*′, *-T^{a3}-C(═O)O—*′, *-T^{a4}-S—*′, or *-T^{a5}-C(═O)S—*′, T^{a1}, T^{a2}, T^{a3}, T^{a4}, and T^{a5} are each independently a chemical bond or a substituted or unsubstituted C1 to C30 divalent hydrocarbon group, R^{a3} is hydrogen or a substituted or unsubstituted C1 to C30 hydrocarbon group, * is a binding site for the ring, CY¹, of Formula 2, and *′ is a binding site for M of Formula 1),

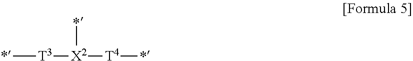

(in Formula 5, X² is S, O, or N(R^{b1}), R^{b1} is hydrogen or a substituted or unsubstituted C1 to C30 hydrocarbon group, T³ and T⁴ are each independently *-T^{b1}-N(R^{b2})—*′, *-T^{b2}-O—*′, *-T^{b3}-C(═O)O—*′, *-T^{b4}-S—*′, or *-T^{b}s-C(═O)S—*′, T^{b1}, T^{b2}, T^{b3}, T^{b4}, and T^{b}s are each independently a chemical bond or a substituted or unsubstituted C1 to C30 divalent hydrocarbon group, R^{b2} is hydrogen or a substituted or unsubstituted C1 to C30 hydrocarbon group, * is a binding site for X² of Formula 5, and *′ is a binding site for M of Formula 1), and

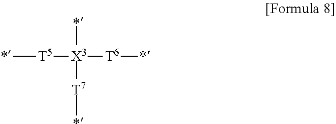

(in Formula 8, X³ is N, T⁵, T⁶, and T⁷ are each independently *-T^{c1}-N(R^{c1})—*′, *-T^{c2}-O—*, *-T^{c3}-C(═O)O—*′, *-T^{c4}-S—*′, or *-T^{c5}-C(═O)S—*′, T^{c1}, T^{c2}, T^{c3}, T^{c4}, and T^{c5} are each independently a chemical bond or a substituted or unsubstituted C1 to C30 divalent hydrocarbon group, R^{c1} is hydrogen or a substituted or unsubstituted C1 to C30 hydrocarbon group, * is a binding site for X³ of Formula 8, and *′ is a binding site for M of Formula 1).

### BRIEF DESCRIPTION OF THE DRAWINGS

Embodiments will be more clearly understood from the following detailed description taken in conjunction with the accompanying drawings in which:

FIGS. 1 to 5 are cross-sectional views respectively illustrating a sequence of processes of a method of fabricating an integrated circuit device, according to some embodiments.

### DETAILED DESCRIPTION OF THE EMBODIMENTS

Hereinafter, embodiments of the inventive concept will be described in detail with reference to the accompanying drawings. Like components are denoted by like reference numerals throughout the specification, and repeated descriptions thereof are omitted.

A photoresist composition according to some embodiments may include an organometallic compound represented by Formula 1 and a solvent.

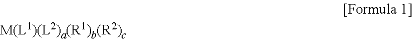

In Formula 1, M may be a metal. In Formula 1, L¹ may be a tridentate ligand or a tetradentate ligand, L² may be a monodenatate ligand or a bidentate ligand, and R¹ and R² may each independently be a substituted or unsubstituted C1 to C30 hydrocarbon group. In Formula 1, a, b, and c may each be an integer that is greater than or equal to 0 and less than or equal to 5, a+b+c may be 5 or less, and b+c may be 1 or more.

In the specification, the tridentate ligand refers to a ligand having three binding sites for M that is a central metal; the tetradentate ligand refers to a ligand having four binding sites for the central metal M; the monodenatate ligand refers to a ligand having one binding site for the central metal M; and the bidentate ligand refers to a ligand having two binding sites for the central metal M. Here, the kind of bond may include a covalent bond and a coordinate bond.

In some embodiments, in Formula 1, M may include at least one metal element selected from Sn, Sb, In, Bi, Ag, Te, Au, Pb, Zn, Ti, Hf, Zr, Al, V, Cr, Co, Ni, Cu, Ga, and Fe. For example, in Formula 1, M may be Sn or Sb.

In some embodiments, in Formula 1, R¹ and R² may each independently be a C1 to C30 chain-shaped (acyclic) or ring-shaped (cyclic) aliphatic hydrocarbon group substitutable with a substituent, or a C6 to C30 aromatic hydrocarbon group substitutable with a substituent. For example, the chain may include a linear chain or a branched chain.

For example, R¹ and R² may each independently be a C1 to C30 alkyl group substitutable with a substituent, a C2 to C30 alkenyl group substitutable with a substituent, a C2 to C30 alkynyl group substitutable with a substituent, a C3 to C30 cycloalkyl group substitutable with a substituent, a C3 to C30 cycloalkenyl group substitutable with a substituent, a C6 to C30 aryl group substitutable with a substituent, a C7 to C30 alkylaryl group substitutable with a substituent, or a C7 to C30 arylaklyl group substitutable with a substituent.

For example, the substituent of each of R¹ and R² may include a hetero atom or a halogen atom and may include a hydroxyl group, a carboxyl group, an amino group, a nitro group, a cyano group, an isocyanate group, a thiol group, a sulfonic acid group, a phosphoric acid group, or a salt thereof.

For example, the aliphatic hydrocarbon group and/or the aromatic hydrocarbon group of each of R¹ and R² may be substituted or connected by at least one selected from the group consisting of —C═C—, —C≡C—, —O—, —S—, —C(═O)—, —OC(═O)O—, —C(═O)O—, —S(═O)—, —C(═O)S—, —C(═O)NR—, —NR′—, —S—S—, and —SO₂—, wherein R and R′ may each independently be a hydrogen atom, a C1 to C8 linear-chain hydrocarbon group, or a C4 to C8 branched-chain hydrocarbon group.

In some embodiments, in Formula 1, L¹ may include at least one electron donor atom. The electron donor atom refers to an atom having at least one unshared electron pair capable of participating in a bond by providing an electron to an empty orbital. For example, the electron donor atom of L¹ may be coordinately bonded with the central atom M by providing an electron to an empty orbital of the central atom M.

In some embodiments, in Formula 1, L¹ may be a substitutable C1 to C30 chain-shaped or ring-shaped aliphatic hydrocarbon group or a substitutable C6 to C30 aromatic hydrocarbon group, which includes at least one heteroatom from among S, O, and N. For example, the chain may include a linear chain or a branched chain.

In some embodiments, in Formula 1, L² may include, but is not limited to, at least one selected from groups represented by Formulae 1-1. In Formulae 1-1, *′ is a binding site for the central metal M.

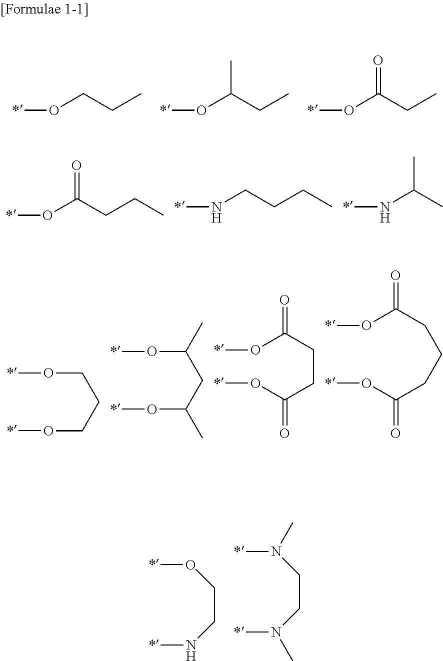

In some embodiments, when L¹ is a tridentate ligand, a+b+c may be 2 or 3, and b+c may be 1 or 2. In some embodiments, when L¹ is a tetradentate ligand, a+b+c may be 1 or 2, and b+c may be 1.

In some embodiments, when L¹ is a tridentate ligand, a+b+c may be 4 or 5, and b+c may be greater than or equal to 1 and less than or equal to 4. In some embodiments, when L¹ is a tetradentate ligand, a+b+c may be 3 or 4, and b+c may be greater than or equal to 1 and less than or equal to 3.

A metal complex compound, which is included in a negative-type photoresist composition, may be crosslinked by exposure to light. An exposed region of a photoresist film formed from a photoresist composition may have reduced solubility in a developer, and as a result, a pattern may be implemented. Although the metal complex compound may have improved sensitivity to light due to high reactivity thereof, there may be an issue in that the metal complex compound loses properties as a component of the photoresist composition due to a side reaction with an external element before, after, or during a photoresist process.

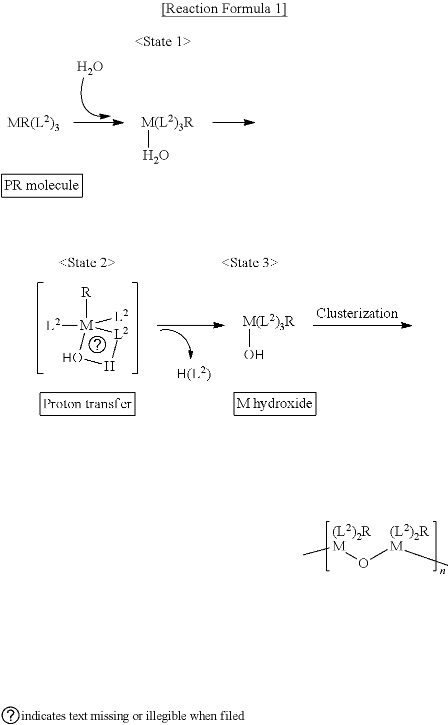

Referring to Reaction Formula 1, a metal complex compound (referred to as a first metal complex compound hereinafter) including only L² bonded to the central metal M reacts with water (H₂O), and then, is self-polymerized, thereby forming a cluster. The first metal complex compound does not include L¹ bonded to the central metal M. Due to a side reaction with external water, the first metal complex compound may have a reduced storage lifespan, and there may be an issue in that the first metal complex compound forms a cluster regardless of exposure to light during or before a photoresist process and thus deteriorates pattern quality.

The organometallic compound of the photoresist composition according to the inventive concept includes L¹ having three or four bonds with the central metal M, and thus, may have reduced reactivity with an external element (for example, water), thereby improving the storage stability of the photoresist composition without deteriorating pattern formation properties of the photoresist composition.

A first state (see State 1 in Reaction Formula 1), in which the organometallic compound is bonded with a water molecule, may be defined. For example, the water molecule may be coordinately bonded to the central metal M. Reaction energy for forming the first state may be understood as binding energy of water (H₂O) (referred to as a first reaction energy hereinafter). In some embodiments, the first reaction energy of the organometallic compound may be greater than or equal to −10 kcal/mol. For example, the first reaction energy of the organometallic compound may be greater than or equal to about −10 kcal/mol and less than or equal to about 20 kcal/mol. In some embodiments, the first reaction energy of the organometallic compound may be greater than or equal to −5 kcal/mol. When the first reaction energy of the organometallic compound is less than or equal to about 20 kcal/mol, a side reaction between the water molecule and the organometallic compound may be inhibited.

A second state (see State 2 in Reaction Formula 1), in which a proton of the water molecule has transferred in the first state of Reaction Formula 1, may be defined. Reaction energy for forming the second state may be understood as energy (referred to as a second reaction energy hereinafter) for forming a transition state in which the proton of the water molecule bonded to the central metal M in the first state is weakly bonded to an adjacent ligand.

In some embodiments, the second state of the organometallic compound may have a higher energy level than a state in which the organometallic compound is not bonded with the water molecule (for example, an initial state before forming the first state). Therefore, the organometallic compound in the first state may prefer to return to the initial state through a reverse reaction rather than form the second state through a reaction.

In some embodiments, the second reaction energy of the organometallic compound may be greater than or equal to 0.05 kcal/mol. In some embodiments, the second reaction energy of the organometallic compound may be greater than or equal to 0.1 kcal/mol. For example, the second reaction energy of the organometallic compound may be greater than or equal to about 0.1 kcal/mol and less than or equal to about 20 kcal/mol. In some embodiments, the second reaction energy of the organometallic compound may be greater than or equal to 0.5 kcal/mol, 1.0 kcal/mol, 3.0 kcal/mol, or 5 kcal/mol.

A third state (see State 3 in Reaction Formula 1), in which, in the second state of Reaction Formula 1, the ligand bonded with the proton of the water molecule leaves the central metal M and a hydroxyl group is bonded to the central metal M, may be defined. For example, reaction energy for forming the third state (referred to as a third reaction energy hereinafter) may be understood as energy for forming a metal hydroxide in the second state.

In some embodiments, the third state of the organometallic compound may have a higher energy level than the first state thereof. For example, an absolute value of the second reaction energy may be greater than an absolute value of the third reaction energy. For example, an absolute value of a difference between an energy level of the first state and an energy level of the second state may be greater than an absolute value of a difference between the energy level of the second state and an energy level of the third state. For example, the first state of the organometallic compound may be stabler than the third state thereof, and the organometallic compound in the second state may prefer to return to the first state rather than form the third state through a reaction.

In some embodiments, the third state of the organometallic compound may have a higher energy level than a state in which the organometallic compound is not bonded with the water molecule (for example, the initial state before forming the first state). Therefore, because the third state is thermodynamically more unstable than the initial state, the organometallic compound may be suppressed from reacting with the water molecule to form a metal hydroxide.

A first bond length, which is a bond length between the central metal M and an atom of a ligand bonded with the central metal M, may be defined. In some embodiments, the first bond length of L¹ of the organometallic compound may be less than or equal to about 2.3 Å, where the bond length is measured between the metal and one of the bonding atoms forming a tridentate or tetradentate ligand. For example, a bond length between the central metal M and an oxygen bonded with the central metal may be less than or equal to about 2.3 Å. In some embodiments, the first bond length of L¹ may be less than or equal to about 2.25 Å, about 2.2 Å, or about 2.15 Å. When the first bond length of L¹ is less than or equal to about 2.3 Å, the coordinate bond structure of the organometallic compound may be stabilized, thereby suppressing a reaction with an external element (for example, a water molecule). In some embodiments, the first bond length of L¹ may refer to a bond length of an atom of L¹, which forms a covalent bond with the central metal M.

A first bond dissociation energy, which is a bond dissociation energy between the central metal M and a hydrocarbon group (for example, R¹ and R²) bonded to the central metal M, may be defined. For example, the hydrocarbon group may refer to a functional group leaving the organometallic compound or having a moiety configured to undergo a crosslinking reaction, where the crosslinking reaction can be due to exposure to light. In some embodiments, the first bond dissociation energy between the central metal M and R¹ or R² of the organometallic compound may be less than or equal to about 90 kcal/mol. In some embodiments, the first bond dissociation energy may be less than or equal to about 85 kcal/mol, about 80 kcal/mol, or about 75 kcal/mol.

When the first bond dissociation energy is less than or equal to about 90 kcal/mol, a film formed of the photoresist composition may be crosslinked at a sensitivity of 70 mJ/cm² or less or 60 mJ/cm² or less and thus implement a difference in solubility in a developer.

Herein, the first reaction energy, the second reaction energy, and the third reaction energy were obtained through a first principles calculation based on density functional theory (DFT). Here, the first principles calculation refers to performing a calculation by using a fundamental equation according to the following Equation 1 without external parameters.

$${E}_{KS} = V + 〈 hP 〉 + 1 / 2 〈 PJ ( P ) 〉 + {E}_{X} [ P ] + {E}_{C} [ P ] \qquad [ Equation 1 ]$$

$$( {E}_{KS} = electronic energy$$

$$V = The nuclear repulsion energy$$

$$P = The density matrix$$

$$〈 hP 〉 = The one - electron kinetic potential energy$$

$$1 / 2 〈 PJ ( P ) 〉 = The classical coulomb repulsion of the electrons$$

$${E}_{X} [ P ] = The exchange functional$$

$${E}_{C} [ P ] = The correlation functional )$$

In a DFT calculation, Gaussian16 code, which is first-principles DFT code, was used, B3LYP was used as a functional, 6-31G** was used as a basis set, for typical elements (H, C, S, O, N, and the like), and LANL2DZ was used as a basis set, for metal elements (Sn, Sb, and the like).

According to some embodiments, in Formula 1, L¹ may be a ligand represented by Formula 2.

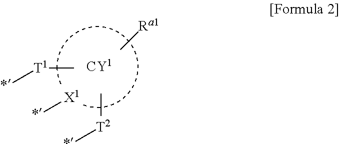

In Formula 2, CY¹, which is a ring, may be a C2 to C30 heterocyclic group. In Formula 2, R^{a1} may be hydrogen or a substituted or unsubstituted C1 to C30 hydrocarbon group, X may be S, O, N, or N(R^{a2}), R^{a2} may be hydrogen or a substituted or unsubstituted C1 to C30 hydrocarbon group, and T¹ and T² may each independently be *-T^{a1}-N(R^{a3})—*′, *-T^{a2}-O—*′, *-T^{a3}-C(═O)O—*′, *-T^{a4}-S—*′, or *-T^{a5}-C(═O)S—*′. Here, T^{a1}, T^{a2}, T^{a3}, and T^{a4} may each independently be a chemical bond or a substituted or unsubstituted C1 to C30 divalent hydrocarbon group, and R^{a3} may be hydrogen or a substituted or unsubstituted C1 to C30 hydrocarbon group. Here, * is a binding site for the ring CY¹ of Formula 2, and *′ is a binding site for M of Formula 1.

In some embodiments, in Formula 2, the ring CY¹ may include at least one heteroatom, and the heteroatom may include S, O, N, or P. In some embodiments, the ring CY¹ may be an aromatic group and/or a non-aromatic group. In some embodiments, the ring CY¹ may be a C2 to C30 heterocycloalkyl group substitutable with a substituent, a C3 to C30 heterocycloalkenyl group substitutable with a substituent, or a C2 to C30 heteroaryl group substitutable with a substituent. For example, the substituent may be another heteroatom.

In some embodiments, the ring CY¹ may include a pyridine group, a pyrimidine group, a pyrazine group, a pyrazine group, an imidazole group, a pyrazole group, an oxadazole group, a furan group, an oxazole group, a pyrrole group, a triazine group, a thiophene group, a thiazole group, a quinoline group, an azacarbazole group, a dibenzofuran group, an azadibenzothiophene group, an azadibenzoselenophene group, an azadibenzosilole group, or an azadibenzoborole group.

In some embodiments, the ring CY¹ may include a piperidine group, a morpholine group, an imidazolidine group, a pyrrolidine group, a piperazine group, or a tetrahydrofuran group.

In some embodiments, in Formula 2, R^{a1} may be a C1 to C30 chain-shaped or ring-shaped aliphatic hydrocarbon group substitutable with a substituent, or a C6 to C30 aromatic hydrocarbon group substitutable with a substituent. For example, the chain may include a linear chain or a branched chain.

For example, R^{a1} may be a C1 to C30 alkyl group substitutable with a substituent, a C2 to C30 alkenyl group substitutable with a substituent, a C2 to C30 alkynyl group substitutable with a substituent, a C3 to C30 cycloalkyl group substitutable with a substituent, a C3 to C30 cycloalkenyl group substitutable with a substituent, a C6 to C30 aryl group substitutable with a substituent, a C7 to C30 alkylaryl group substitutable with a substituent, or a C7 to C32 arylalkyl group substitutable with a substituent. For example, the substituent of R^{a1} may include a heteroatom or a halogen atom and may include a hydroxyl group, a carboxyl group, an amino group, a nitro group, a cyano group, an isocyanate group, a thiol group, a sulfonic acid group, a phosphoric acid group, or a salt thereof.

For example, the aliphatic hydrocarbon group and/or the aromatic hydrocarbon group of R^{a1} may be substituted or connected by at least one selected from the group consisting of —C═C—, —C≡C—, —O—, —S—, —C(═O)—, —OC(═O)O—, —C(═O)O—, —S(═O)—, —C(═O)S—, —C(═O)NR—, —NR′—, —S—S—, and —SO₂—, wherein R and R′ may each independently be a hydrogen atom, a C1 to C8 linear-chain hydrocarbon group, or a C4 to C8 branched-chain hydrocarbon group.

In some embodiments, in Formula 2, X¹ may include an electron donor atom, and the electron donor atom may form a coordinate bond with the central metal M of Formula 1. For example, the electron donor atom of X¹ may be S, O, or N.

In some embodiments, in Formula 2, R^{a2} and R^{a3} may each independently be a C1 to C30 linear-chain or branched-chain aliphatic hydrocarbon group substitutable with a substituent. For example, each of R^{a2} and R^{a3} may be a C1 to C30 alkyl group substitutable with a substituent, a C2 to C30 alkenyl group substitutable with a substituent, or a C2 to C30 alkynyl group substitutable with a substituent.

For example, each of R^{a2} and R^{a3} may include a heteroatom or a halogen atom and may include a hydroxyl group, a carboxyl group, an amino group, a nitro group, a cyano group, an isocyanate group, a thiol group, a sulfonic acid group, a phosphoric acid group, or a salt thereof.

For example, the aliphatic hydrocarbon group of each of R^{a2} and R^{a3} may be substituted or connected by at least one selected from the group consisting of —C═C—, —C≡C—, —O—, —S—, —C(═O)—, —OC(═O)O—, —C(═O)O—, —S(═O)—, —C(═O)S—, —C(═O)NR—, —NR′—, —S—S—, and —SO₂—, wherein R and R′ may each independently be a hydrogen atom, a C1 to C8 linear-chain hydrocarbon group, or a C4 to C8 branched-chain hydrocarbon group.

In some embodiments, T^{a1}, T^{a2}, T^{a3}, T^{a4}, and T^{a5} may each independently be a C1 to C30 divalent chain-shape or ring-shape aliphatic hydrocarbon group substitutable with a substituent, or a C6 to C30 divalent aromatic hydrocarbon group substitutable with a substituent. For example, the chain may include a linear chain or a branched chain.

For example, T^{a1}, T^{a2}, T^{a3}, T^{a4}, and T^{a5} may each independently be a C1 to C30 alkylene group substitutable with a substituent, a C2 to C30 alkenylene group substitutable with a substituent, a C2 to C30 alkynylene group substitutable with a substituent, a C3 to C30 cycloalkylene group substitutable with a substituent, a C3 to C30 cycloalkenylene group substitutable with a substituent, a C3 to C30 cycloalkynylene group substitutable with a substituent, a C6 to C30 arylene group substitutable with a substituent, a C7 to C30 alkylarylene group substitutable with a substituent, or a C7 to C30 arylalkylene group substitutable with a substituent.

For example, the substituent of each of T^{a1}, T^{a2}, T^{a3}, T^{a4}, and T^{a5} may include a heteroatom or a halogen atom and may include a hydroxyl group, a carboxyl group, an amino group, a nitro group, a cyano group, an isocyanate group, a thiol group, a sulfonic acid group, a phosphoric acid group, or a salt thereof.

In some embodiments, the aliphatic hydrocarbon group and/or the aromatic hydrocarbon group of each of Ta, T^{a2}, T^{a3}, T^{a4}, and T^{a5} may be substituted or connected by at least one selected from the group consisting of —C═C—, —C≡C—, —O—, —S—, —C(═O)—, —OC(═O)O—, —C(═O)O—, —S(═O)—, —C(═O)S—, —C(═O)NR—, —NR′—, —S—S—, and —SO₂—, wherein R and R′ may each independently be a hydrogen atom, a C1 to C8 linear-chain hydrocarbon group, or a C4 to C8 branched-chain hydrocarbon group.

In some embodiments, in Formula 2, T¹ and T² may be the same as each other. In some embodiments, in Formula 2, T¹ and T² may be located symmetric to each other about a plane passing through X¹ and the central metal M. Therefore, a stabler complex compound structure may be formed, thereby suppressing a side reaction with an external element. In some embodiments, in Formula 2, T¹ and T² may be different from each other.

In some embodiments, the organometallic compound may be represented by Formula 3 or 4.

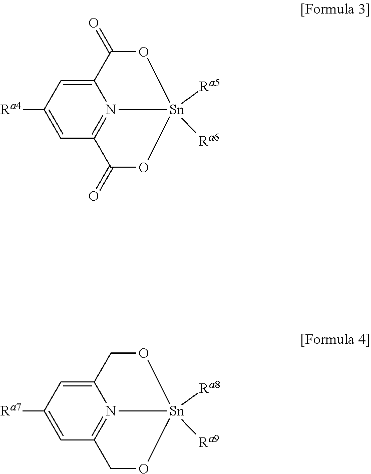

In Formula 3 and Formula 4, R^{a4}, R^{a5}, R^{a6}, R^{a7}, R^{a8}, and R^{a9} may each independently be a substituted or unsubstituted C1 to C30 hydrocarbon group.

In some embodiments, R^{a4}, R^{a5}, R^{a6}, R^{a7}, R^{a8}, and R^{a9} may each independently be a C1 to C30 chain-shape or ring-shape aliphatic hydrocarbon group substitutable with a substituent, or a C6 to C30 aromatic hydrocarbon group substitutable with a substituent. For example, the chain may include a linear chain or a branched chain.

For example, R^{a4}, R^{a5}, R^{a6}, R^{a7}, R^{a8}, and R^{a9} may each independently be a C1 to C30 alkyl group substitutable with a substituent, a C2 to C30 alkenyl group substitutable with a substituent, a C2 to C30 alkynyl group substitutable with a substituent, a C3 to C30 cycloalkyl group substitutable with a substituent, a C3 to C30 cycloalkenyl group substitutable with a substituent, a C3 to C30 cycloalkynyl group substitutable with a substituent, a C6 to C30 aryl group substitutable with a substituent, a C7 to C30 alkylaryl group substitutable with a substituent, or a C7 to C30 arylalkyl group substitutable with a substituent. For example, the substituent of each of R^{a4}, Ras, R^{a6}, R^{a7}, R^{a8}, and R^{ag} may include a heteroatom or a halogen atom and may include a hydroxyl group, a carboxyl group, an amino group, a nitro group, a cyano group, an isocyanate group, a thiol group, a sulfonic acid group, a phosphoric acid group, or a salt thereof.

For example, the aliphatic hydrocarbon group and/or the aromatic hydrocarbon group of each of R^{a4}, R^{a5}, R^{a6}, R^{a7}, R^{a8}, and R^{a9} may be substituted or connected by at least one selected from the group consisting of —C═C—, —C≡C—, —O—, —S—, —C(═O)—, —OC(═O)O—, —C(═O)O—, —S(═O)—, —C(═O)S—, —C(═O)NR—, —NR′—, —S—S—, and —SO₂—, wherein R and R′ may each independently be a hydrogen atom, a C1 to C8 linear-chain hydrocarbon group, or a C4 to C8 branched-chain hydrocarbon group.

According to some embodiments, in Formula 1, L¹ may be a ligand represented by Formula 5.

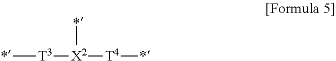

In Formula 5, X² may be S, O, or N(R^{b1}), and R^{b1} may be hydrogen or a substituted or unsubstituted C1 to C30 hydrocarbon group. In Formula 5, T³ and T⁴ may each independently be *-T^{b1}-N(R^{b2})—*′, *-T^{b2}-O—*′, *-T^{b3}-C(═O)O—*′, *-T^{b4}-S—*′, or *-T^{b5}-C(═O)S—*′. Here, T^{b1}, T^{b2}, T^{b3}, and T¹ may each independently be a chemical bond or a substituted or unsubstituted C1 to C30 divalent hydrocarbon group, and R^{b2} may be hydrogen or a substituted or unsubstituted C1 to C30 hydrocarbon group. Here, * is a binding site for X² of Formula 5, and *′ is a binding site for M of Formula 1.

In some embodiments, in Formula 5, X² may include an electron donor atom, and the electron donor atom may form a coordinate bond with the central metal M of Formula 1. For example, the electron donor atom of X² may be S, O, or N.

In some embodiments, in Formula 5, R^{b1} and R^{b2} may each independently be a C1 to C30 linear-chain or branched-chain aliphatic hydrocarbon group substitutable with a substituent. For example, each of R^{b1} and R^{b2} may be a C1 to C30 alkyl group substitutable with a substituent, a C2 to C30 alkenyl group substitutable with a substituent, or a C2 to C30 alkynyl group substitutable with a substituent.

For example, the substituent of each of R^{b1} and R^{b2} may include a heteroatom or a halogen atom and may include a hydroxyl group, a carboxyl group, an amino group, a nitro group, a cyano group, an isocyanate group, a thiol group, a sulfonic acid group, a phosphoric acid group, or a salt thereof.

For example, the aliphatic hydrocarbon group of each of R^{b1} and R^{b2} may be substituted or connected by at least one selected from the group consisting of —C═C—, —C≡C—, —O—, —S—, —C(═O)—, —OC(═O)O—, —C(═O)O—, —S(═O)—, —C(═O)S—, —C(═O)NR—, —NR′—, —S—S—, and —SO₂—, wherein R and R′ may each independently be a hydrogen atom, a C1 to C8 linear-chain hydrocarbon group, or a C4 to C8 branched-chain hydrocarbon group.

In some embodiments, T^{b1}, T^{b2}, T^{b3}, T^{b4}, and T^{b}s may each independently be a C1 to C30 divalent chain-shape or ring-shape aliphatic hydrocarbon group substitutable with a substituent, or a C6 to C30 divalent aromatic hydrocarbon group substitutable with a substituent. For example, the chain may include a linear chain or a branched chain.

For example, T^{b1}, T^{b2}, T^{b3}, T^{b4}, and T^{b}s may each independently be a C1 to C30 alkylene group substitutable with a substituent, a C2 to C30 alkenylene group substitutable with a substituent, a C2 to C30 alkynylene group substitutable with a substituent, a C3 to C30 cycloalkylene group substitutable with a substituent, a C3 to C30 cycloalkenylene group substitutable with a substituent, a C3 to C30 cycloalkynylene group substitutable with a substituent, a C6 to C30 arylene group substitutable with a substituent, a C7 to C30 alkylarylene group substitutable with a substituent, or a C7 to C30 arylalkylene group substitutable with a substituent.

For example, the substituent of each of T^{b1}, T^{b2}, T^{b3}, T^{b4}, and T^{b}s may include a heteroatom or a halogen atom and may include a hydroxyl group, a carboxyl group, an amino group, a nitro group, a cyano group, an isocyanate group, a thiol group, a sulfonic acid group, a phosphoric acid group, or a salt thereof.

In some embodiments, the aliphatic hydrocarbon group and/or the aromatic hydrocarbon group of each of T^{b1}, T^{b2}, T^{b3}, T^{b4}, and T^{b}s may be substituted or connected by at least one selected from the group consisting of —C═C—, —C≡C—, —O—, —S—, —C(═O)—, —OC(═O)O—, —C(═O)O—, —S(═O)—, —C(═O)S—, —C(═O)NR—, —NR′—, —S—S—, and —SO₂—, wherein R and R′ may each independently be a hydrogen atom, a C1 to C8 linear-chain hydrocarbon group, or a C4 to C8 branched-chain hydrocarbon group.

In some embodiments, in Formula 5, T³ and T⁴ may be the same as each other. In some embodiments, in Formula 5, T³ and T⁴ may be located symmetric to each other about a plane passing through X² and the central metal M. In some embodiments, in Formula 5, T³ and T⁴ may be different from each other.

In some embodiments, the organometallic compound may be represented by Formula 6 or 7.

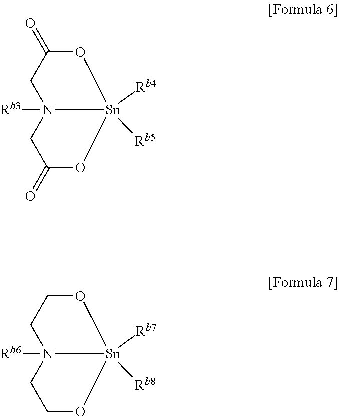

In Formula 6 and Formula 7, R^{b3}, R^{b4}, R^{b5}, R^{b6}, R^{b7}, and R^{b8} may each independently be a substituted or unsubstituted C1 to C30 hydrocarbon group.

In some embodiments, R^{b3}, R^{b4}, R^{b5}, R^{b6}, R^{b7}, and R^{b8} may each independently be a C1 to C30 chain-shape or ring-shape aliphatic hydrocarbon group substitutable with a substituent, or a C6 to C30 aromatic hydrocarbon group substitutable with a substituent. For example, the chain may include a linear chain or a branched chain.

For example, R^{b3}, R^{b4}, R^{b5}, R^{b6}, R^{b7}, and R^{b8} may each independently be a C1 to C30 alkyl group substitutable with a substituent, a C2 to C30 alkenyl group substitutable with a substituent, a C2 to C30 alkynyl group substitutable with a substituent, a C3 to C30 cycloalkyl group substitutable with a substituent, a C3 to C30 cycloalkenyl group substitutable with a substituent, a C6 to C30 aryl group substitutable with a substituent, a C7 to C30 alkylaryl group substitutable with a substituent, or a C7 to C32 arylalkyl group substitutable with a substituent. For example, the substituent of each of R^{b3}, R^{b4}, R^{b5}, R^{b6}, R^{b7}, and R^{b8} may include a heteroatom or a halogen atom and may include a hydroxyl group, a carboxyl group, an amino group, a nitro group, a cyano group, an isocyanate group, a thiol group, a sulfonic acid group, a phosphoric acid group, or a salt thereof.

For example, the aliphatic hydrocarbon group and/or the aromatic hydrocarbon group of each of R^{b3}, R^{b4}, R^{b5}, R^{b6}, R^{b7}, and R^{b8} may be substituted or connected by at least one selected from the group consisting of —C═C—, —C≡C—, —O—, —S—, —C(═O)—, —OC(═O)O—, —C(═O)O—, —S(═O)—, —C(═O)S—, —C(═O)NR—, —NR′—, —S—S—, and —SO₂—, wherein R and R′ may each independently be a hydrogen atom, a C1 to C8 linear-chain hydrocarbon group, or a C4 to C8 branched-chain hydrocarbon group.

According to some embodiments, in Formula 1, L¹ may be a ligand represented by Formula 8.

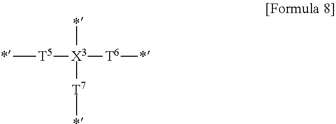

In Formula 8, X³ may be N, T⁵, T⁶, and T⁷ may each independently be *-T^{c1}-N(R^{c1})—*, *-T^{c2}-O—*′, *-T^{c3}-C(═O)O—*′, *-T^{c4}-S—*′, or *-T^{c5}-C(═O)S—*′, Tel, T^{c2}, T^{c3}, T^{c4}, and TcS may each independently be a chemical bond or a substituted or unsubstituted ^{c1} to C30 divalent hydrocarbon group, and R^{c1} may be hydrogen or a substituted or unsubstituted ^{c1} to C30 hydrocarbon group. Here, * is a binding site for X³ of Formula 8, and *′ is a binding site for M of Formula 1.

In some embodiments, in Formula 8, N of X³ may be an electron donor atom, and the electron donor atom may form a coordinate bond with the central metal M of Formula 1.

In some embodiments, in Formula 8, R^{c1} may be a ^{c1} to C30 linear-chain or branched-chain aliphatic hydrocarbon group substitutable with a substituent. For example, R^{c1} may be a ^{c1} to C30 alkyl group substitutable with a substituent, a C2 to C30 alkenyl group substitutable with a substituent, or a C2 to C30 alkynyl group substitutable with a substituent.

For example, the substituent of R^{c1} may include a heteroatom or a halogen atom and may include a hydroxyl group, a carboxyl group, an amino group, a nitro group, a cyano group, an isocyanate group, a thiol group, a sulfonic acid group, a phosphoric acid group, or a salt thereof.

For example, the aliphatic hydrocarbon group of R^{c1} may be substituted or connected by at least one selected from the group consisting of —C═C—, —C≡C—, —O—, —S—, —C(═O)—, —OC(═O)O—, —C(═O)O—, —S(═O)—, —C(═O)S—, —C(═O)NR—, —NR′—, —S—S—, and —SO₂—, wherein R and R′ may each independently be a hydrogen atom, a C1 to C8 linear-chain hydrocarbon group, or a C4 to C8 branched-chain hydrocarbon group.

In some embodiments, T^{c1}, T^{c2}, T^{c3}, T^{c4}, and T^{c5} may each independently be a C1 to C30 divalent chain-shape or ring-shape aliphatic hydrocarbon group substitutable with a substituent, or a C6 to C30 divalent aromatic hydrocarbon group substitutable with a substituent. For example, the chain may include a linear chain or a branched chain.

For example, T^{c1}, T^{c2}, T^{c3}, T^{c4}, and T^{c5} may each independently be a C1 to C30 alkylene group substitutable with a substituent, a C2 to C30 alkenylene group substitutable with a substituent, a C2 to C30 alkynylene group substitutable with a substituent, a C3 to C30 cycloalkylene group substitutable with a substituent, a C3 to C30 cycloalkenylene group substitutable with a substituent, a C3 to C30 cycloalkynylene group substitutable with a substituent, a C6 to C30 arylene group substitutable with a substituent, a C7 to C30 alkylarylene group substitutable with a substituent, or a C7 to C30 arylalkylene group substitutable with a substituent.

For example, the substituent of each of T^{c1}, T^{c2}, T^{c3}, T^{c4}, and T^{c}s may include a heteroatom or a halogen atom and may include a hydroxyl group, a carboxyl group, an amino group, a nitro group, a cyano group, an isocyanate group, a thiol group, a sulfonic acid group, a phosphoric acid group, or a salt thereof.

In some embodiments, the aliphatic hydrocarbon group and/or the aromatic hydrocarbon group of each of T^{c1}, T^{c2}, T^{c3}, T^{c4}, and T^{c}s may be substituted or connected by at least one selected from the group consisting of —C═C—, —C≡C—, —O—, —S—, —C(═O)—, —OC(═O)O—, —C(═O)O—, —S(═O)—, —C(═O)S—, —C(═O)NR—, —NR′—, —S—S—, and —SO₂—, wherein R and R′ may each independently be a hydrogen atom, a C1 to C8 linear-chain hydrocarbon group, or a C4 to C8 branched-chain hydrocarbon group.

In some embodiments, in Formula 8, T⁵, T⁶, and T⁷ may be the same as each other. In some embodiments, in Formula 8, T⁵, T⁶, and T⁷ may be located symmetric to each other about X³. In some embodiments, in Formula 8, T⁵, T⁶, and T⁷ may be different from each other.

In some embodiments, the organometallic compound may be represented by Formula 9 or 10.

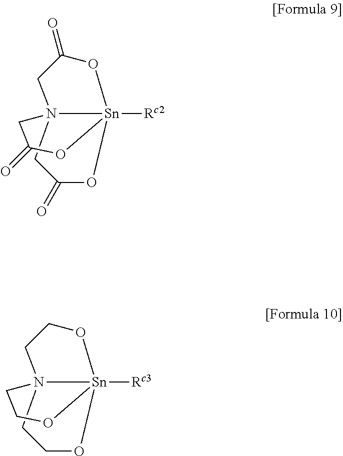

In Formula 9 and Formula 10, R^{c2} and R^{c3} may each independently be a substituted or unsubstituted C1 to C30 hydrocarbon group.

In some embodiments, R^{c2} and R^{c3} may each independently be a C1 to C30 chain-shape or ring-shape aliphatic hydrocarbon group substitutable with a substituent, or a C6 to C30 aromatic hydrocarbon group substitutable with a substituent. For example, the chain may include a linear chain or a branched chain.

For example, R^{c2} and R^{c3} may each independently be a C1 to C30 alkyl group substitutable with a substituent, a C2 to C30 alkenyl group substitutable with a substituent, a C2 to C30 alkynyl group substitutable with a substituent, a C3 to C30 cycloalkyl group substitutable with a substituent, a C3 to C30 cycloalkenyl group substitutable with a substituent, a C6 to C30 aryl group substitutable with a substituent, a C7 to C30 alkylaryl group substitutable with a substituent, or a C7 to C32 arylalkyl group substitutable with a substituent. For example, the substituent of each of R^{c2} and R^{c3} may include a heteroatom or a halogen atom and may include a hydroxyl group, a carboxyl group, an amino group, a nitro group, a cyano group, an isocyanate group, a thiol group, a sulfonic acid group, a phosphoric acid group, or a salt thereof.

For example, the aliphatic hydrocarbon group and/or the aromatic hydrocarbon group of each of R^{c2} and R^{c3} may be substituted or connected by at least one selected from the group consisting of —C═C—, —C≡C—, —O—, —S—, —C(═O)—, —OC(═O)O—, —C(═O)O—, —S(═O)—, —C(═O)S—, —C(═O)NR—, —NR′—, —S—S—, and —SO₂—, wherein R and R′ may each independently be a hydrogen atom, a C1 to C8 linear-chain hydrocarbon group, or a C4 to C8 branched-chain hydrocarbon group.

In the photoresist composition according to some embodiments, the organometallic compound may be present in an amount of about 0.05% by weight (wt %) to about 30 wt %, based on a total weight of the photoresist composition. In some embodiments, the organometallic compound may be present in an amount of about 0.1 wt % to about 25 wt %, about 1 wt % to about 20 wt %, about 1 wt % to about 15 wt %, or about 1 wt % to about 10 wt %, based on the total weight of the photoresist composition. Within the range set forth above, the storage stability of the photoresist composition may improve without deteriorating a capability of forming a photoresist film by using the photoresist composition.

According to some embodiments, the solvent of the photoresist composition may include an organic solvent. The organic solvent may include, but is not limited to, at least one of ethers, alcohols, glycol ethers, aromatic hydrocarbon compounds, ketones, and esters. For example, the organic solvent may include ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (which may be alternatively referred to as methyl isobutyl carbinol (MIBC)), hexanol, 1-methoxy-2-propanol, 1-ethoxy-2-propanol, ethylene glycol, propylene glycol, heptanone, propylene carbonate, butylene carbonate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl 2-hydroxyisobutyrate, methoxybenzene, n-butyl acetate, 1-methoxy-2-propyl acetate, methoxyethoxy propionate, ethoxyethoxy propionate, or a combination thereof.

In the photoresist composition according to some embodiments, the solvent may be present in an amount of about 70 wt % to about 99.95 wt %, based on the total weight of the photoresist composition. In some embodiments, the solvent may be present in an amount of about 75 wt % to about 99.9 wt %, about 80 wt % to about 99.9 wt %, about 85 wt % to about 99 wt %, or about 90 wt % to about 99 wt %, based on the total weight of the photoresist composition.

In some embodiments, the photoresist composition may further include at least one selected from a surfactant, a dispersant, a moisture absorber, and a coupling agent.

The surfactant may improve the coating uniformity and wettability of the photoresist composition. According to some embodiments, the surfactant may include, but is not limited to, a sulfuric acid ester salt, a sulfonic acid salt, phosphoric acid ester, soap, an amine salt, a quaternary ammonium salt, polyethylene glycol, an alkylphenol ethylene oxide adduct, a polyhydric alcohol, a nitrogen-containing vinyl polymer, or a combination thereof. For example, the surfactant may include an alkylbenzene sulfonic acid salt, an alkylpyridinium salt, polyethylene glycol, or a quaternary ammonium salt. When the photoresist composition includes the surfactant, the surfactant may be present in an amount of about 0.001 wt % to about 3 wt %, based on the total weight of the photoresist composition.

The dispersant may cause respective components constituting the photoresist composition to be uniformly dispersed in the photoresist composition. According to some embodiments, the dispersant may include, but is not limited to, an epoxy resin, polyvinyl alcohol, polyvinyl butyral, polyvinylpyrrolidone, glucose, sodium dodecyl sulfate, sodium citrate, oleic acid, linoleic acid, or a combination thereof. When the photoresist composition includes the dispersant, the dispersant may be present in an amount of about 0.001 wt % to about 5 wt %, based on the total weight of the photoresist composition.

The moisture absorber may additionally prevent adverse effects thereon due to water in the photoresist composition. For example, the moisture absorber may prevent a metal in the photoresist composition from being oxidized by water. According to some embodiments, the moisture absorber may include, but is not limited to, polyoxyethylene nonylphenolether, polyethylene glycol, polypropylene glycol, polyacrylamide, or a combination thereof. When the photoresist composition includes the moisture absorber, the moisture absorber may be present in an amount of about 0.001 wt % to about 10 wt %, based on the total weight of the photoresist composition.

In some embodiments, the photoresist composition may include the organometallic compound having a stable structure, thereby suppressing a side reaction with an external element including water. Therefore, even when the photoresist composition does not include the moisture absorber separately or includes the moisture absorber in an extremely low amount, the photoresist composition may prevent adverse effects thereon due to water.

The coupling agent may improve adhesion of the photoresist composition to an underlying film, when the photoresist composition is coated on the underlying film. According to some embodiments, the coupling agent may include a silane coupling agent. The silane coupling agent may include, but is not limited to, vinyltrimethoxysilane, vinyltriethoxysilane, vinyltrichlorosilane, vinyltris(β-methoxyethoxy)silane, 3-methacryloxypropyltrimethoxysilane, 3-acryloxypropyltrimethoxysilane, p-styryltrimethoxysilane, 3-methacryloxypropylmethyldimethoxysilane, 3-methacryloxypropylmethyldiethoxysilane, or trimethoxy[3-(phenylamino)propyl]silane. When the photoresist composition includes the coupling agent, the coupling agent may be present in an amount of about 0.001 wt % to about 5 wt %, based on the total weight of the photoresist composition.

Hereinafter, a method of fabricating an integrated circuit device by using the photoresist composition according to the inventive concept is described by taking specific examples.

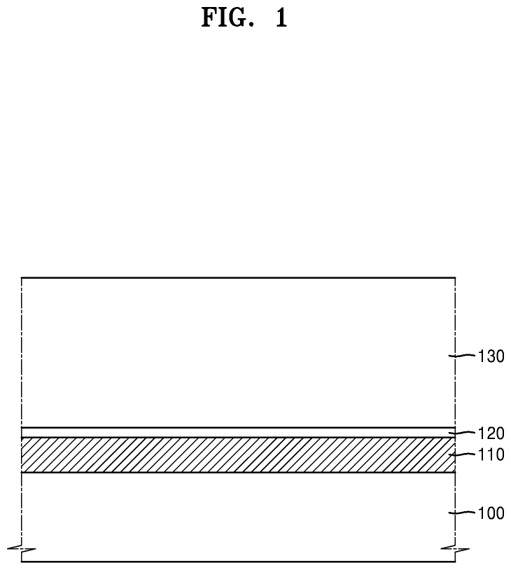

FIGS. 1 to 5 are cross-sectional views respectively illustrating a sequence of processes of a method of fabricating an integrated circuit device, according to some embodiments.

Referring to FIG. 1, a feature layer 110 is formed on a substrate 100, and a photoresist film 130 is formed on the feature layer 110 by using the photoresist composition according to the inventive concept. The photoresist film 130 may include an organometallic compound, which is a component of the photoresist composition. A more detailed configuration of the photoresist composition is the same as described above.

The substrate 100 may include a semiconductor substrate. The feature layer 110 may include an insulating film, a conductive film, or a semiconductor film. For example, the feature layer 110 may include, but is not limited to, a metal, an alloy, a metal carbide, a metal nitride, a metal oxynitride, a metal oxycarbide, a semiconductor, polysilicon, an oxide, a nitride, an oxynitride, or a combination thereof.

According to some embodiments, before the photoresist film 130 is formed on the feature layer 110, a developable bottom anti-reflective coating (DBARC) film 120 may be formed on the feature layer 110. In this case, the photoresist film 130 may be formed on the DBARC film 120.

The DBARC film 120 may control the diffused reflection of light emitted from a light source, which is used in an exposure process for fabricating an integrated circuit device, or may absorb light reflected by the feature layer 110 thereunder. According to some embodiments, the DBARC film 120 may include an organic anti-reflective coating (ARC) material for a KrF excimer laser, for an ArF excimer laser, for an EUV laser, or for other light sources. According to some embodiments, the DBARC film 120 may include an organic component having a light-absorption structure. The light-absorption structure may include, for example, a hydrocarbon compound having a structure in which one or more benzene rings are fused. The DBARC film 120 may have a thickness of about 20 nm to about 100 nm, but the inventive concept is not limited thereto.

To form the photoresist film 130, the photoresist composition according to the inventive concept may be coated on the DBARC film 120 and then be heat-treated. The coating may be performed by a method, such as spin coating, spray coating, or dip coating. The process of heat-treating the photoresist composition may be performed at a temperature in a range of about 80° C. to about 300° C. for about 10 seconds to about 100 seconds, but the inventive concept is not limited thereto. The thickness of the photoresist film 130 may be tens to hundreds of times the thickness of the DBARC film 120. The photoresist film 130 may have a thickness of about 100 nm to about 6 μm, but the inventive concept is not limited thereto.

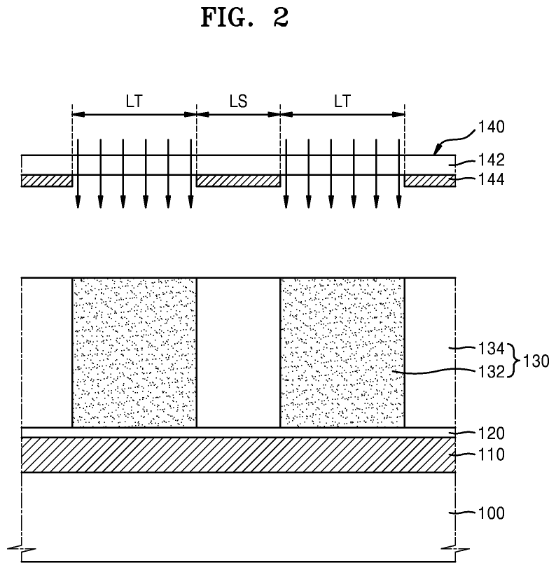

Referring to FIG. 2, a first region 132, which is a portion of the photoresist film 130, is exposed to light.

While the photoresist film 130 is exposed to light, the organometallic compound, which is included in the photoresist film 130 in the first region 132, may be crosslinked, and thus, a network of a metal structure may be densely formed. Therefore, a difference in solubility in a developer between the exposed first region 132 and a non-exposed second region 134 of the photoresist film 130 may increase.

According to the inventive concept, the organometallic compound of the photoresist composition used to form the photoresist film 130 may include a tridentate ligand or a tetradentate ligand, which has three or four binding sites for the central metal M, and thus, may form a stable complex compound structure. Therefore, in storing the photoresist composition before the photoresist film 130 is formed, or in forming the photoresist film 130, the photoresist composition may be prevented from reacting with water in air or in equipment, and as a result, good-quality pattern formation properties may be achieved.

To expose the first region 132 of the photoresist film 130 to light, a photomask 140, which has a plurality of light-shielding areas LS and a plurality of light-transmitting areas LT, may be aligned at a certain position above the photoresist film 130, and the first region 132 of the photoresist film 130 may be exposed to light through the plurality of light-transmitting areas LT of the photomask 140. To expose the first region 132 of the photoresist film 130 to light, a KrF excimer laser (248 nm), an ArF excimer laser (193 nm), an F₂ excimer laser (157 nm), or an EUV laser (13.5 nm) may be used.

The photomask 140 may include a transparent substrate 142, and a plurality of light-shielding patterns 144 formed on the transparent substrate 142 in the plurality of light-shielding areas LS. The transparent substrate 142 may include quartz. The plurality of light-shielding patterns 144 may include chromium (Cr). The plurality of light-transmitting areas LT may be defined by the plurality of light-shielding patterns 144. According to the inventive concept, to expose the first region 132 of the photoresist film 130 to light, a reflective photomask for EUV exposure may be used instead of the photomask 140.

After the first region 132 of the photoresist film 130 is exposed to light, the photoresist film 130 may undergo annealing. The annealing may be performed at a temperature of about 50° C. to about 200° C. for about 10 seconds to about 100 seconds, but the inventive concept is not limited thereto.

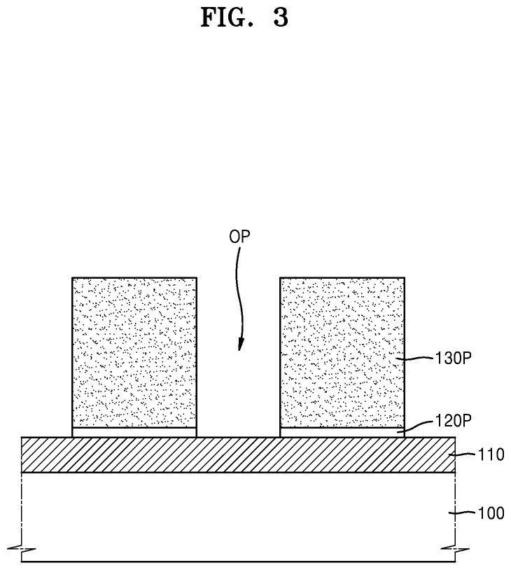

Referring to FIG. 3, a photoresist pattern 130P is formed by developing the exposed photoresist film 130.

According to some embodiments, the non-exposed second region 134 of the photoresist film 130 may be removed by developing the exposed photoresist film 130 shown in FIG. 2, and the photoresist pattern 130P, which includes the exposed first region 132 of the photoresist film 130, may be formed. The photoresist pattern 130P may include a plurality of openings OP. A DBARC pattern 120P may be formed by removing portions of the DBARC film 120, which are exposed by the plurality of openings OP.

According to some embodiments, the development of the photoresist film 130 may be performed by a negative-tone development (NTD) process. Here, n-butyl acetate or 2-heptanone may be used as the developer, but the developer is not limited thereto.

According to some embodiments, to develop the exposed photoresist film 130, various developers may be used. For example, 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, amyl acetate, butenyl acetate, isoamyl acetate, phenyl acetate, propyl formate, butyl formate, isobutyl formate, amyl formate, isoamyl formate, methyl valerate, methyl pentenate, methyl crotonate, ethyl crotonate, methyl propionate, ethyl propionate, 3-ethoxyethyl propionate, methyl lactate, ethyl lactate, propyl lactate, butyl lactate, isobutyl lactate, amyl lactate, isoamyl lactate, 2-hydroxymethyl isobutyrate, ethyl-2-hydroxy isobutyrate, methyl benzoate, ethyl benzoate, phenyl acetate, benzyl acetate, phenylmethyl acetate, benzyl formate, phenylethyl formate, methyl-3-phenylpropionate, benzyl propionate, ethyl phenyl acetate, 2-phenylethyl acetate, or a combination thereof may be used as the developer, but the inventive concept is not limited thereto.

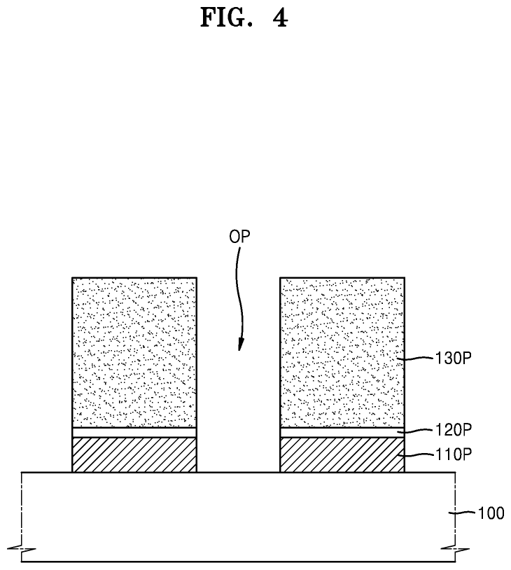

Referring to FIG. 4, in a resulting product of FIG. 3, the feature layer 110 is processed by using the photoresist pattern 130P.

For example, to process the feature layer 110, various processes, such as a process of etching the feature layer 110 exposed by the openings OP of the photoresist pattern 130P, a process of implanting impurity ions into the feature layer 110, a process of forming an additional film on the feature layer 110 through the openings OP, and a process of modifying portions of the feature layer 110 through the openings OP, may be performed. As an example, process of processing the feature layer 110, FIG. 4 illustrates an example of forming a feature pattern 110P by etching the feature layer 110 exposed by the openings OP.

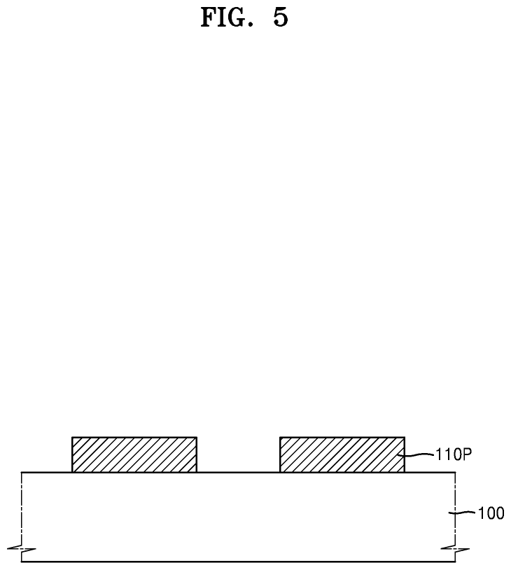

Referring to FIG. 5, in a resulting product of FIG. 4, the photoresist pattern 130P and the DBARC pattern 120P, which remain on the feature pattern 110P, can be removed. To remove the photoresist pattern 130P and the DBARC pattern 120P, ashing and strip processes may be used.

Hereinafter, although experimental examples including specific examples and comparative examples are described for helping the understanding of the inventive concept, these are only examples, and the inventive concept is not limited to the following examples.

### SYNTHESIS EXAMPLE

### Synthesis Example 1: Preparation of Organometallic Compound A-1

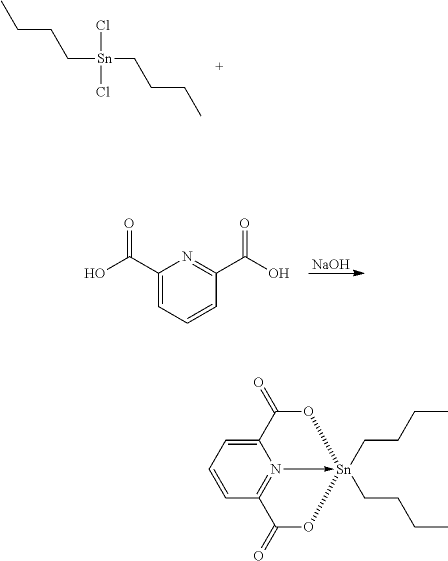

30 ml of an aqueous solution including 0.05 g (0.003 mol, 1 eq) of dipicolinic acid and 0.0075 mol (2.5 eq) of sodium hydroxide was moved into an emulsion container mounted on a blender (model 1120, Waring Co., Ltd.), followed by stirring the aqueous solution at 1800 rpm at a temperature of 25° C. During the stirring, 30 ml of a hexane solution including 0.91 g (0.003 mol, 1 eq) of dibutyltin dichloride was added into the emulsion container for about 3 to about 4 seconds. A produced solution was blended for 15 seconds, and then, a precipitate was recovered. After the precipitate was recovered by vacuum filtration, unreacted materials and impurities were removed by cleaning the precipitate with deionized water and hexane twice or three times, followed by drying the precipitate at room temperature, thereby obtaining 0.82 g (57%) of a compound represented by Formula 11.

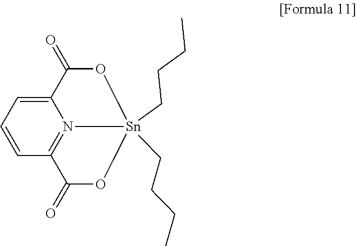

### Synthesis Example 2: Preparation of Organometallic Compound A-2

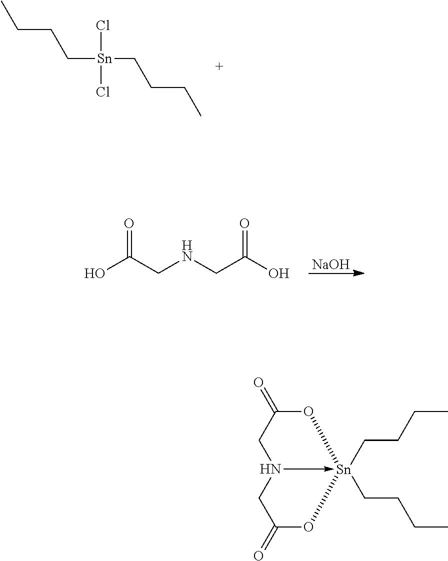

Synthesis was performed in the same manner as in Synthesis Example 1 except that 0.003 mol (1 eq) of iminodiacetic acid was used instead of dipicolinic acid, thereby obtaining 0.79 g (58%) of a compound represented by Formula 12.

The compound represented by Formula 12 was obtained.

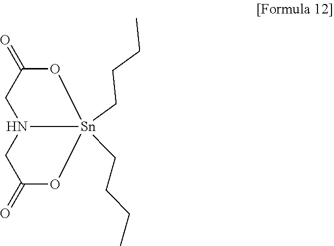

### Synthesis Example 3: Preparation of Organometallic Compound A-3

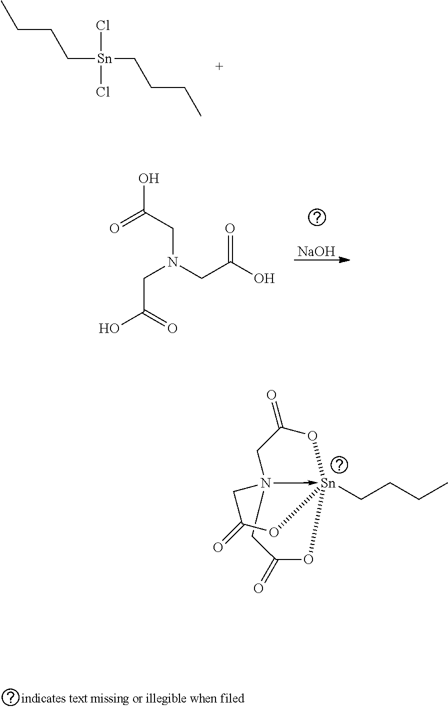

Synthesis was performed in the same manner as in Synthesis Example 1 except that 0.003 mol (1 eq) of nitrilotriacetic acid was used instead of dipicolinic acid, thereby obtaining 0.75 g (51%) of a compound represented by Formula 13.

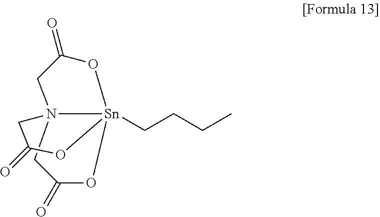

### Synthesis Example 4: Preparation of Organometallic Compound A-4

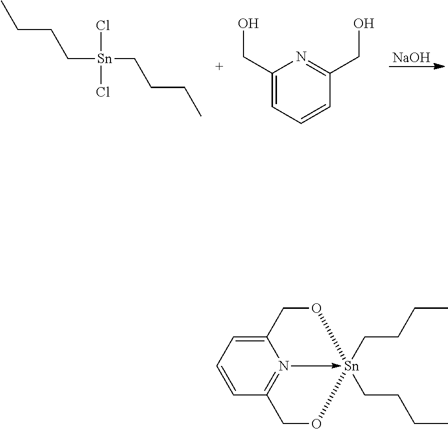

Synthesis was performed in the same manner as in Synthesis Example 1 except that 0.003 mol (1 eq) of 2,6-pyridinedimethanol was used instead of dipicolinic acid, thereby obtaining 0.79 g (60%) of a compound represented by Formula 14.

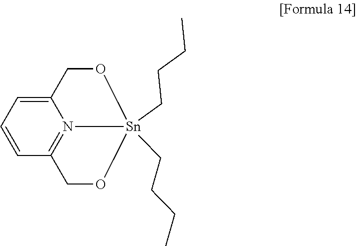

### Comparative Synthesis Example 1: Preparation of Organometallic Compound B-1

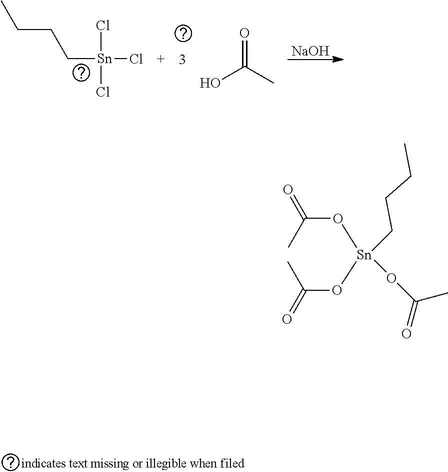

25 ml of acrylic acid was slowly added dropwise to 10 g (0.025 mol) of monobutyltin trichloride, followed by performing reflux by heating the components at 80° C. for 6 hours. The temperature of the components was adjusted to 25° C., followed by performing vacuum distillation of acrylic acid, thereby obtaining a compound represented by Formula 15 at a yield of 50%.

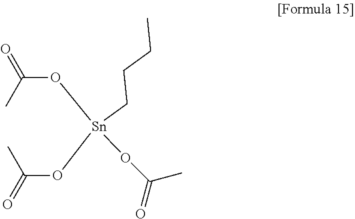 [SMILES: CCC[CH2][Sn]([O]C(C)=O)([O]C(C)=O)[O]C(C)=O]

### EVALUATION EXAMPLE

### Evaluation Example 1

For each of the organometallic compound A-1 represented by Formula 11 and the organometallic compound B-1 represented by Formula 15, an energy level change value due to a reaction with a water molecule was obtained by performing a DFT calculation using Gaussian 16 code. A B3LYP/LanL2DZ function was used for a metal of an organometallic compound, and a B3LYP/6-31G** function was used for a typical element thereof. Reaction Formula 2 illustrates a reaction between the organometallic compound A-1 and a water molecule, and Reaction Formula 3 illustrates a reaction between the organometallic compound B-1 and a water molecule.

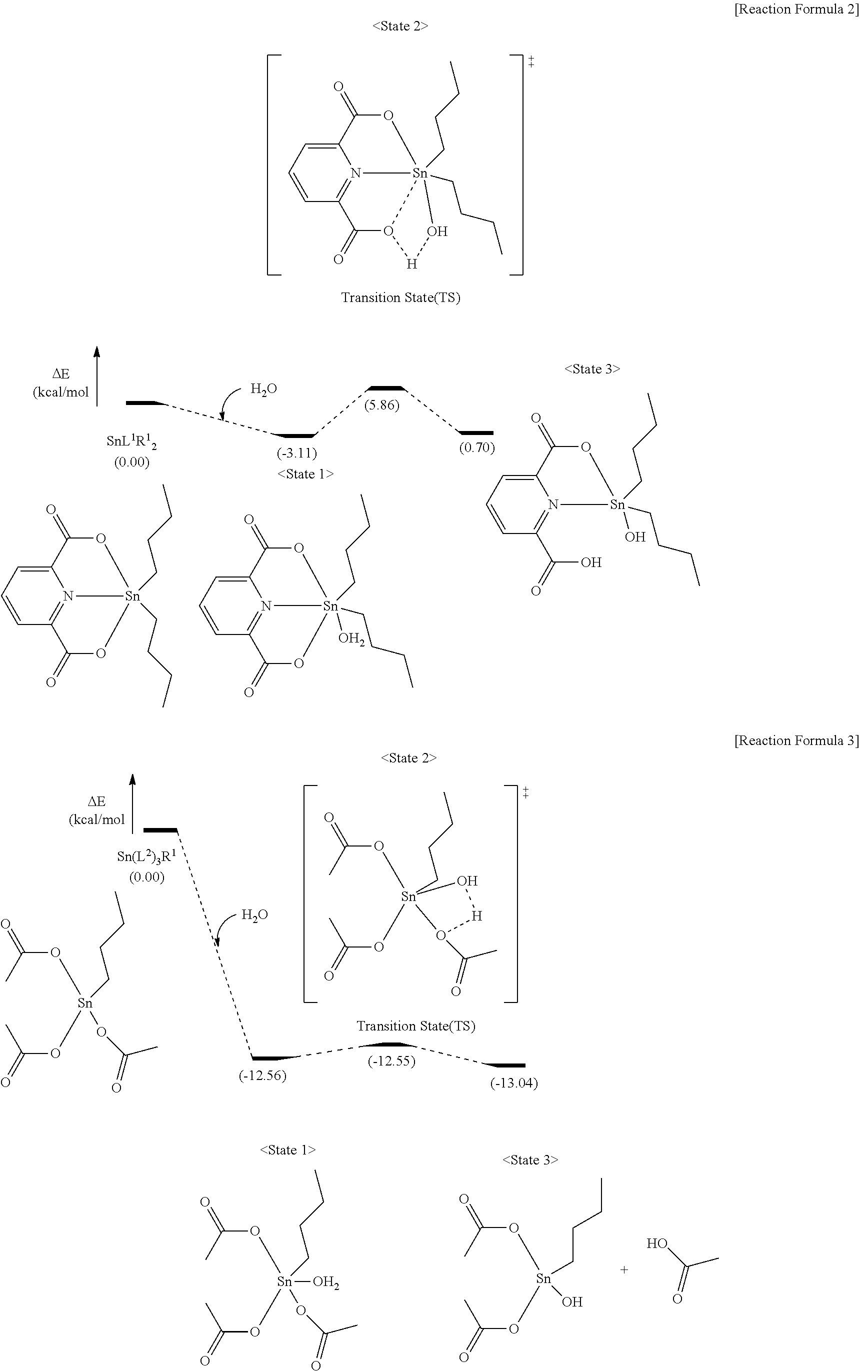

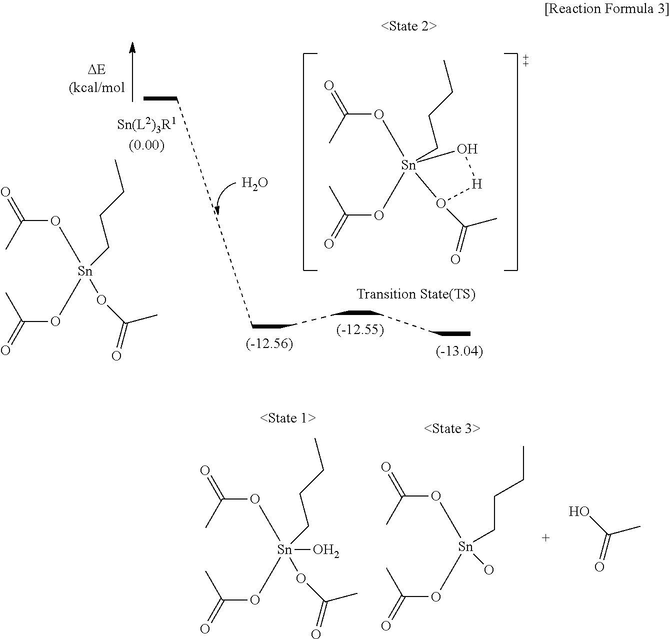

Referring together to Reaction Formula 2 and Reaction Formula 3, the first reaction energy for the organometallic compound A-1 to form the first state was calculated as −3.11 kcal/mol, and the first reaction energy for the organometallic compound B-1 to form the first state was calculated as −12.56 kcla/mol. In addition, it could be confirmed that the organometallic compound B-1 is higher than the organometallic compound A-1 in terms of a degree of being stabilized by reaction with a water molecule, and that the organometallic compound B-1 more prefers a change to the first state than the organometallic compound A-1.

It could be confirmed that, while the second reaction energy for the organometallic compound B-1 in the first state to form the second state is 0.01 kcal/mol which is relatively extremely low, the second reaction energy of the organometallic compound A-1 is 8.97 kcal/mol which is relatively high when viewed from a relative perspective. In addition, it could be confirmed that the second reaction energy of the organometallic compound A-1 is higher than reaction energy (3. 11 kcal/mol) of a reverse reaction for the organometallic compound A-1 in the first state to return to a state (that is, an initial state) before the organometallic compound A-1 reacts with a water molecule. Furthermore, it could be confirmed that, while the energy level of the second state of the organometallic compound A-1 is higher than the energy level of the initial state of the organometallic compound A-1, the energy level of the second state of the organometallic compound B-1 is lower than the energy level of the initial state of the organometallic compound B-1.

It could be confirmed that the energy level of the third state of the organometallic compound B-1 is lower than the energy level of the first state of the organometallic compound B-1, and that the organometallic compound B-1 more prefers a reaction of changing to the third state from the second state than a reaction of returning to the first state from the second state. On the other hand, the energy level of the third state of the organometallic compound A-1 was calculated to be higher than the energy level of the first state of the organometallic compound A-1, and it could be confirmed that the organometallic compound A-1 more prefers a reaction of returning to the first state from the second state than a reaction of changing to the third state from the second state. In addition, it could be confirmed that, while the energy level of the third state of the organometallic compound B-1 is lower than the energy level of the initial state of the organometallic compound B-1, the energy level of the third state of the organometallic compound A-1 is higher than the energy level of the initial state of the organometallic compound A-1. When viewed from a relative perspective, it could be confirmed that, while the organometallic compound B-1 prefers to form a cluster by reaction with water in terms of thermodynamics and chemical kinetics, the organometallic compound A-1 is suppressed from reacting with water.

### Evaluation Example 2

Through the same DFT calculations as in Evaluation Example 1, depending on the kinds of organometallic compounds, a first bond length (M-Y bond distance) between the central metal M and an atom of a ligand (L¹ and/or L²), which is bonded to the central metal M, a first reaction energy for an organometallic compound in the initial state to form the first state of being bonded with a water molecule, and a first bond dissociation energy (M-R BDE) of a hydrocarbon group (R) bonded to M of an organometallic compound were calculated, thereby obtaining values of Table 1.

TABLE 1

| | | M—Y bond | First reaction | |
|---|---|---|---|---|
| | Organometallic | distance | energy | M—R BDE |
| | compound | (Å) | (kcal/mol) | (kcal/mol) |
| Example 1 | A-1 | 2.12 | −3.11 | 66.05 |
| Example 2 | A-2 | 2.08 | −3.05 | 65.17 |
| Example 3 | A-3 | 2.04 | 6.89 | 69.75 |
| Example 4 | A-4 | 2.02 | 7.69 | 71.38 |
| Comparative | B-1 | 2.31 | −12.56 | 66.23 |
| Example 1 | | | | |

Referring to Table 1, it could be confirmed that each of the organometallic compounds A-1 to A-4 according to Examples 1 to 4 has a first bond length less than the first bond length of the organometallic compound B-1 according to Comparative Example 1 and has a first reaction energy higher than the first reaction energy of the organometallic compound B-1 according to Comparative Example 1, when viewed from a relative perspective. When viewed from a relative perspective, it could be confirmed that each of the organometallic compounds A-1 to A-4 according to Examples 1 to 4 has a stable structure in the initial state thereof and is suppressed from reacting with water.

In addition, each of the organometallic compounds A-1 to A-4 according to Examples 1 to 4 had a first bond dissociation energy that is less than or equal to 75 kcal/mol. It could be anticipated that, by exposure to light, the hydrocarbon group (R) of each of the organometallic compounds A-1 to A-4 according to Examples 1 to 4 may leave each of the organometallic compounds A-1 to A-4 or be crosslinked, thereby allowing a photoresist film to be easily formed.

While the inventive concept has been particularly shown and described with reference to embodiments thereof, it will be understood that various changes in form and details may be made therein without departing from the spirit and scope of the following claims.

What is claimed is:

1. A photoresist composition comprising an organometallic compound represented by Formula 1:
M(L¹)(L²)ₐ(R′)_{b}(R²)c, [Formula 1]
where in Formula 1, M is a metal,
L¹ is a tridentate ligand or a tetradentate ligand,
L² is a monodenatate ligand or a bidentate ligand,
R¹ and R² are each independently a substituted or unsubstituted C1 to C30 hydrocarbon group, and
a, b, and c are each an integer of 0, 1, or 2, a+b+c≤5, and 1≤b+c.

2. The photoresist composition of claim 1, wherein, in Formula 1, M is a metal selected from the group consisting of Sn, Sb, In, Bi, Ag, Te, Au, Pb, Zn, Ti, Hf, Zr, Al, V, Cr, Co, Ni, Cu, Ga, and Fe.

3. The photoresist composition of claim 1, wherein, in Formula 1, L¹ is a ligand represented by Formula 2: 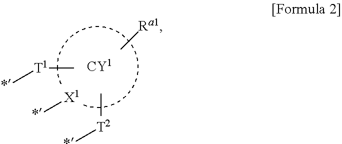
where in Formula 2,
CY¹, which is a ring, is a C2 to C30 heterocyclic group,
R^{a1} is hydrogen or a substituted or unsubstituted C1 to C30 hydrocarbon group,
X¹ is S, O, N, or N(R^{a2}), R^{a2} is hydrogen or a substituted or unsubstituted C1 to C30 hydrocarbon group,
T¹ and T² are each independently *-T^{a1}-N(R^{a3})—*′, *-T^{a2}-O—*′, *-T^{a3}-C(═O)O—*′, *-T^{a4}-S—*′, or *-T^{a5}-C(═O)S—*′,
T^{a1}, T^{a2}, T^{a3}, T^{a4}, and T^{a5} are each independently a chemical bond or a substituted or unsubstituted C1 to C30 divalent hydrocarbon group,
R^{a3} is hydrogen or a substituted or unsubstituted C1 to C30 hydrocarbon group,
*is a binding site for the ring, CY¹, of Formula 2, and
*′ is a binding site for M of Formula 1.

4. The photoresist composition of claim 3, wherein, in Formula 1, M is coordinately bonded with an electron donor atom of X¹ of Formula 2, and
the electron donor atom of X¹ is selected from the group consisting of S, O, and N.

5. The photoresist composition of claim 3, wherein, in Formula 2, T¹ and T² are the same as each other.

6. The photoresist composition of claim 1, wherein the organometallic compound is represented by Formula 3 or 4: 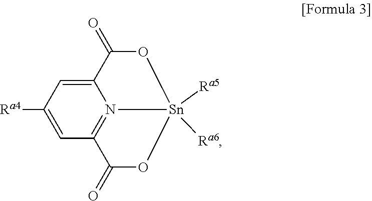
where in Formula 3, R^{a4}, R^{a5}, and R^{a6} are each independently a substituted or unsubstituted C1 to C30 hydrocarbon group, and 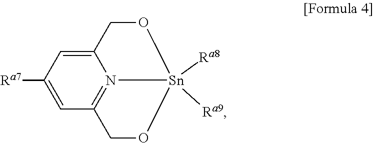
(in Formula 4, R^{a7}, R^{a8}, and R^{a9} are each independently a substituted or unsubstituted C1 to C30 hydrocarbon group).

7. The photoresist composition of claim 1, wherein, in Formula 1, L¹ is a group represented by Formula 5: 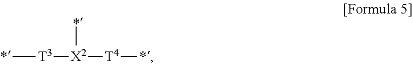
where in Formula 5,
X² is S, O, or N(R^{b1}), R^{b1} is hydrogen or a substituted or unsubstituted C1 to C30 hydrocarbon group,
T³ and T⁴ are each independently *-T^{b1}-N(R^{b2})—*′, *-T^{b2}-O—*′, *-T^{b3}-C(═O)O—*′, *-T^{b4}-S—*′, or *-T^{b5}-C(═O)S—*′,
T^{b1}, T^{b2}, T^{b3}, T^{b4}, and T^{b5} are each independently a chemical bond or a substituted or unsubstituted C1 to C30 divalent hydrocarbon group,
R^{b2} is hydrogen or a substituted or unsubstituted C1 to C30 hydrocarbon group,
* is a binding site for X² of Formula 5, and
*′ is a binding site for M of Formula 1.

8. The photoresist composition of claim 1, wherein the organometallic compound is represented by Formula 6 or 7: 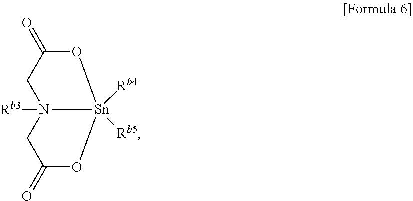
where in Formula 6, R^{b3}, R^{b4}, and R^{b5} are each independently a substituted or unsubstituted C1 to C30 hydrocarbon group, and 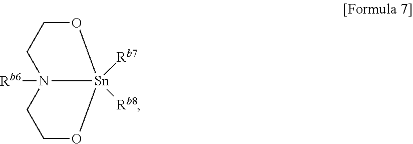
where in Formula 7, R^{b6}, R^{b7}, and R^{b}s are each independently a substituted or unsubstituted C1 to C30 hydrocarbon group.

9. The photoresist composition of claim 1, wherein, in Formula 1, L^{t} is a group represented by Formula 8: 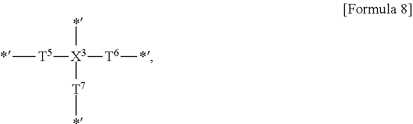
where in Formula 8,
X³ is N,
T⁵, T⁶, and T⁷ are each independently *-T^{c1}-N(R^{c1})—*′, *-T^{c2}-O—*′, *-T^{c3}-C(═O)O—*′, *-T^{c4}-S—*′, or *-T^{c5}-C(═O)S—*′,
T^{c1}, T^{c2}, T^{c3}, T^{c4}, and T^{c}S are each independently a chemical bond or a substituted or unsubstituted ^{c1} to C30 divalent hydrocarbon group,
R^{c1} is hydrogen or a substituted or unsubstituted ^{c1} to C30 hydrocarbon group,
* is a binding site for X³ of Formula 8, and
*′ is a binding site for M of Formula 1.

10. The photoresist composition of claim 1, wherein the organometallic compound is represented by Formula 9 or 10: 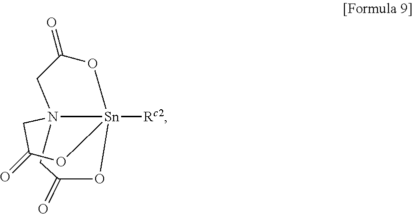
where in Formula 9, R^{c2} is a substituted or unsubstituted C1 to C30 hydrocarbon group, and 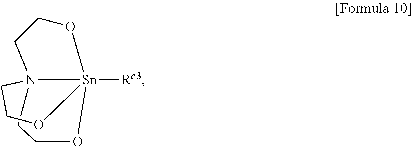
where in Formula 10, R^{c3} is a substituted or unsubstituted C1 to C30 hydrocarbon group.

11. The photoresist composition of claim 1, wherein, in Formula 1, a+b+c is 3, and b+c is 1 or 2.

12. The photoresist composition of claim 1, wherein, in Formula 1, a+b+c is 1, and b+c is 1.

13. A photoresist composition comprising an organometallic compound represented by Formula 1: 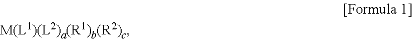
where in Formula 1, M, which is a central metal, is Sn or Sb,
L¹ is a tridentate ligand or a tetradentate ligand,
L² is a monodenatate ligand or a bidentate ligand,
R¹ and R² are each independently a substituted or unsubstituted C1 to C30 hydrocarbon group, and
a, b, and c are each an integer of 0, 1, or 2, a+b+c≤5, and 1≤b+c.

14. The photoresist composition of claim 13, wherein a first reaction energy for the organometallic compound to form a first state in which a water molecule (H₂O) is bonded to the central metal M of the organometallic compound is greater than or equal to −10 kcal/mol, and
the first reaction energy is calculated based on density functional theory (DFT).

15. The photoresist composition of claim 14, wherein an energy level of a second state, in which a proton of the water molecule of the first state is bonded to L¹ that is adjacent thereto, is higher than an energy level of an initial state, in which no water molecule is bonded to the central metal M of the organometallic compound.

16. The photoresist composition of claim 15, wherein an energy level of a third state, in which a metal hydroxide structure is formed by leaving the proton of the second state, is higher than the energy level of the initial state, in which no water molecule is bonded to the central metal M of the organometallic compound.

17. The photoresist composition of claim 16, wherein an absolute value of a difference between an energy level of the first state and the energy level of the second state is greater than an absolute value of a difference between the energy level of the second state and the energy level of the third state.

18. A photoresist composition comprising:
an organometallic compound represented by Formula 1; and
a solvent, 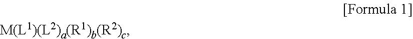
where in Formula 1, M, which is a central metal, is Sn or Sb,
L¹ is one of the following ligands represented by Formula 2, Formula 5, and Formula 8,
L² is a monodenatate ligand or a bidentate ligand,
R¹ and R² are each independently a substituted or unsubstituted C1 to C30 hydrocarbon group,
a, b, and c are each an integer of 0, 1, or 2, a+b+c≤5, and 1≤b+c, 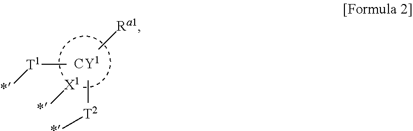
where in Formula 2,
CY¹, which is a ring, is a C2 to C30 heterocyclic group,
R^{a1} is hydrogen or a substituted or unsubstituted C1 to C30 hydrocarbon group,
X¹ is S, O, N, or N(R^{a2}), R^{a2} is hydrogen or a substituted or unsubstituted C1 to C30 hydrocarbon group,
T¹ and T² are each independently *-T^{a1}-N(R^{a3})—*′, *-T^{a2}-O—*′, *-T^{a3}-C(═O)O—*′, *-T^{a4}-S—*, or *-T^{a5}-C(═O)S—*′,
T^{a1}, T^{a2}, T^{a3}, T^{a4}, and T^{a5} are each independently a chemical bond or a substituted or unsubstituted C1 to C30 divalent hydrocarbon group,
R^{a3} is hydrogen or a substituted or unsubstituted C1 to C30 hydrocarbon group,
* is a binding site for the ring, CY¹, of Formula 2, and
*′ is a binding site for M of Formula 1, 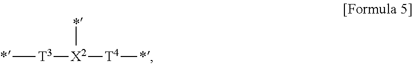
where in Formula 5,
X² is S, O, or N(R^{b1}), R^{b1} is hydrogen or a substituted or unsubstituted C1 to C30 hydrocarbon group,
T³ and T⁴ are each independently *-T^{b1}-N(R^{b2})—*′, *-T^{b2}-O—*′, *-T^{b3}-C(═O)O—*′, *-T^{b4}-S—*′, or *-T^{b5}-C(═O)S—*′,
T^{b1}, T^{b2}, T^{b3}, T^{b4}, and T^{b5} are each independently a chemical bond or a substituted or unsubstituted C1 to C30 divalent hydrocarbon group,
R^{b2} is hydrogen or a substituted or unsubstituted C1 to C30 hydrocarbon group,
* is a binding site for X² of Formula 5, and
*′ is a binding site for M of Formula 1, and 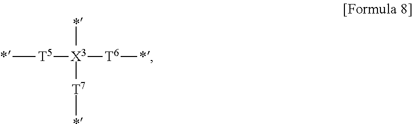
where in Formula 8,
X³ is N,
T⁵, T⁶, and T⁷ are each independently *-T^{c1}-N(R^{c1})—*′, *-T^{c2}-O—*′, *-T^{c3}-C(═O)O—*′, *-T^{c4}-S—*′, or *-T^{c5}-C(═O)S—*′,
T^{c1}, T^{c2}, T^{c3}, T^{c4}, and T^{c5} are each independently a chemical bond or a substituted or unsubstituted ^{c1} to C30 divalent hydrocarbon group,
R^{c1} is hydrogen or a substituted or unsubstituted ^{c1} to C30 hydrocarbon group,
*is a binding site for X³ of Formula 8, and
*′ is a binding site for M of Formula 1.

19. The photoresist composition of claim 18, wherein each of X¹ of Formula 2, X² of Formula 5, and X³ of Formula 8 comprises an electron donor atom, and
the electron donor atom is coordinately bonded to the central metal M of Formula 1.

20. The photoresist composition of claim 18, wherein the organometallic compound is represented by Formula 3, 4, 6, 7, 9, or 10: 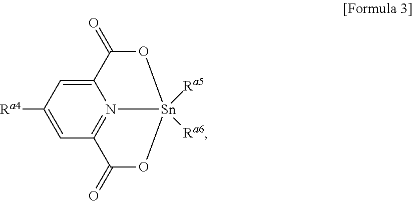
where in Formula 3, R^{a4}, R^{a5}, and R^{a6} are each independently a substituted or unsubstituted C1 to C30 hydrocarbon group, 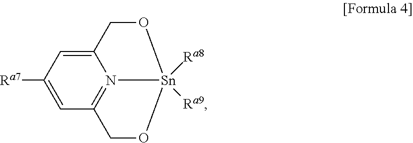
where in Formula 4, R^{a7}, R^{a8}, and R^{a9} are each independently a substituted or unsubstituted C1 to C30 hydrocarbon group, 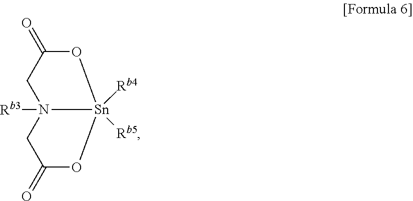
where in Formula 6, R^{b3}, R^{b4}, and R^{b5} are each independently a substituted or unsubstituted C1 to C30 hydrocarbon group, 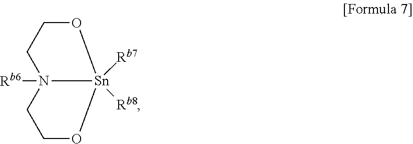
where in Formula 7, R^{b6}, R^{b7}, and R^{b8} are each independently a substituted or unsubstituted C1 to C30 hydrocarbon group, 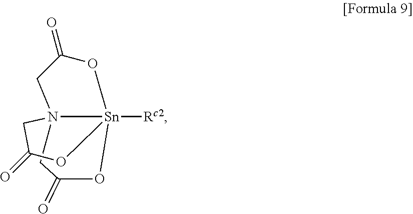
where in Formula 9, R^{c2} is a substituted or unsubstituted C1 to C30 hydrocarbon group, and 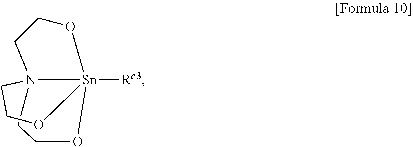
where in Formula 10, R^{c3} is a substituted or unsubstituted C1 to C30 hydrocarbon group.
